(19) United States
(12) Patent Application Publication
(10) Pub. No.: US 2025/0098358 A1
(43) Pub. Date: Mar. 20, 2025

(54) IMAGE SENSING DEVICE INCLUDING SOURCE FOLLOWER TRANSISTOR

(71) Applicant: SK hynix Inc., Icheon-si (KR)

(72) Inventors: Young Gyu YOU, Icheon-si (KR); Dong Joo YANG, Icheon-si (KR)

(21) Appl. No.: 18/623,316

(22) Filed: Apr. 1, 2024

(30) Foreign Application Priority Data
Sep. 14, 2023 (KR) 10-2023-0122368

(51) Int. Cl. H01L 27/146; H04N 25/77

(52) U.S. Cl. CPC H10F 39/813; H04N 25/77; H10F 39/8037; H10F 39/807; H10F 39/811

(57) ABSTRACT

An image sensing device including a source follower transistor is disclosed. The image sensing device includes first and second photoelectric conversion elements that supported by the semiconductor substrate and are spaced apart from each other, a first pixel isolation structure recessed from the second surface and configured to surround the first and second photoelectric conversion elements; second and third pixel isolation structures disposed between the first photoelectric conversion element and the second photoelectric conversion element and spaced apart from each other; and a source follower transistor supported by the semiconductor substrate and configured to include a gate disposed on the second surface in at least a portion of a gap region between the second pixel isolation structure and the third pixel isolation structure.

### CROSS-REFERENCE TO RELATED APPLICATION

This patent document claims the priority and benefits of Korean patent application No. 10-2023-0122368, filed on Sep. 14, 2023, the disclosure of which is incorporated by reference in its entirety as part of the disclosure of this patent document.

### TECHNICAL FIELD

The technology and implementations disclosed in this patent document generally relate to an image sensing device, and more particularly to an image sensing device including a source follower transistor.

### BACKGROUND

An image sensing device is a device for capturing at least one image using semiconductor characteristics that react to light incident thereon to produce an image. In recent times, with the increasing development of information technology (IT) industries and related technologies, the demand for high-quality and high-performance image sensing devices has been rapidly increasing in various electronic devices, for example, smartphones, digital cameras, etc.

Image sensing devices may be broadly classified into CCD (Charge Coupled Device)-based image sensing devices and CMOS (Complementary Metal Oxide Semiconductor)-based image sensing devices. Unlike in the past, CMOS image sensing devices have been intensively researched and rapidly come into widespread use.

### SUMMARY

Various embodiments of the disclosed technology relate to an image sensing device with a structure that allows to secure a larger area for a gate region of a source follower transistor to reduce the amount of noise.

In accordance with an embodiment of the disclosed technology, an image sensing device may include a semiconductor substrate configured to include a first surface upon which light is incident from a scene and a second surface facing or opposite to the first surface; first and second photoelectric conversion elements that are supported by the semiconductor substrate and are spaced apart from each other, each photoelectric conversion element configured to receive incident light and generate photocharges by sensing the incident light; a first pixel isolation structure recessed from the second surface and configured to surround the first and second photoelectric conversion elements; second and third pixel isolation structures disposed between the first photoelectric conversion element and the second photoelectric conversion element and spaced apart from each other; and a gate of a source follower transistor supported by the semiconductor substrate and configured to include a gate disposed on the second surface in at least a portion of a gap region between the second pixel isolation structure and the third pixel isolation structure.

In some implementations, the gate of the source follower transistor may be disposed to overlap at least one of the first and second photoelectric conversion elements.

In some implementations, each of the second pixel isolation structure and the third pixel isolation structure may be in contact with the first pixel isolation structure.

In some implementations, the image sensing device may further include a fourth pixel isolation structure disposed in the gap region.

In some implementations, the image sensing device may further include: a first floating diffusion region configured to store photocharges that are generated by the first photoelectric conversion element in response to the incident light; and a second floating diffusion region configured to store photocharges that are generated by the second photoelectric conversion element in response to the incident light.

In some implementations, the image sensing device may further include: a first transfer transistor having a first terminal electrically connected to the first photoelectric conversion element and a second terminal electrically connected to the first floating diffusion region; and a second transfer transistor having a first terminal electrically connected to the second photoelectric conversion element and a second terminal electrically connected to the second floating diffusion region.

In some implementations, the gate of the first transfer transistor may overlap the first photoelectric conversion element, and may be disposed on the second surface of the semiconductor substrate to be spaced apart from a gate of the source follower transistor; and the gate of the second transfer transistor may overlap the second photoelectric conversion element, and may be disposed on the second surface of the semiconductor substrate to be spaced apart from the gate of the source follower transistor.

In some implementations, a gate of the first transfer transistor may include a structure that is recessed from the second surface toward an inside of the semiconductor substrate, and may be disposed within the semiconductor substrate to be spaced apart from the first floating diffusion region; and a gate of the second transfer transistor may include a structure that is recessed from the second surface toward the inside of the semiconductor substrate, and may be disposed within the semiconductor substrate to be spaced apart from the second floating diffusion region.

In some implementations, the image sensing device may further include a reset transistor supported by the semiconductor substrate and structured to include a gate that overlaps the first photoelectric conversion element, and is disposed on the second surface of the semiconductor substrate to be spaced apart from a gate of the source follower transistor, wherein the reset transistor is configured to drain photocharges stored in first and second floating diffusion regions.

In some implementations, the image sensing device may further include a selection transistor supported by the semiconductor substrate and structured to include a gate that overlaps the second photoelectric conversion element, and is disposed on the second surface of the semiconductor substrate to be spaced apart from a gate of the source follower transistor, wherein the selection transistor outputs an electrical signal having a voltage level corresponding to the photocharges generated by the first or second photoelectric conversion element.

In some implementations, the image sensing device may further include a drain transistor supported by the semiconductor substrate and structured to include a gate that overlaps the first photoelectric conversion element, and is disposed on the second surface of the semiconductor substrate to be spaced apart from a gate of the source follower transistor, wherein the photocharges generated by the first or second photoelectric conversion element are reset by the drain transistor.

In some implementations, the image sensing device may further include a dual conversion gain (DCG) transistor supported by the semiconductor substrate and structured to include a gate that overlaps the first photoelectric conversion element, and is disposed on the second surface of the semiconductor substrate to be spaced apart from a gate of the source follower transistor, wherein the DCG transistor changes a capacitance of at least one of the first transistor and the second transistor.

In some implementations, the imaging sensing device may further include a metal interconnect layer configured to contact each of the first floating diffusion region and the second floating diffusion region while being located outside the semiconductor substrate, wherein the metal interconnect layer electrically connects the first floating diffusion region and the second floating diffusion region to each other.

In accordance with another embodiment of the disclosed technology, an image sensing device may include a semiconductor substrate configured to include a first surface upon which light is incident and a second surface facing or opposite to the first surface; a first photoelectric conversion element supported by the semiconductor substrate and configured to generate photocharges in response to the incident light; a second photoelectric conversion element supported by the semiconductor substrate and spaced apart from the first photoelectric conversion element, and configured to generate photocharges in response to the incident light; and a source follower transistor supported by the substrate and structured to include a gate disposed in a gap region between the first photoelectric conversion element and the second photoelectric conversion element, wherein a gate of the source follower transistor overlaps at least a portion of each of the first photoelectric conversion element and the second photoelectric conversion element that are arranged in a first direction perpendicular to the second surface.

In some implementations, the image sensing device may further include: a first transfer transistor supported by the semiconductor substrate and structured to include a gate that overlaps the first photoelectric conversion element in the first direction and is disposed on the second surface of the semiconductor substrate to be spaced apart from a gate of the source follower transistor; and a second transfer transistor supported by the semiconductor substrate and structured to include a gate that overlaps the second photoelectric conversion element in the first direction and is disposed on the second surface of the semiconductor substrate to be spaced apart from both the gate of the source follower transistor and the gate of the first transfer transistor.

In some implementations, the image sensing device may further include a floating diffusion region supported by the semiconductor substrate within a space between the gate of the first transfer transistor and the gate of the second transfer transistor, and arranged adjacent to the second surface of the semiconductor substrate.

In some implementations, the image sensing device may further include a first floating diffusion region spaced apart from the gate of the first transfer transistor, disposed within the semiconductor substrate, and adjacent to the second surface; and a second floating diffusion region spaced apart from the gate of the second transfer transistor, disposed within the semiconductor substrate, and adjacent to the second surface.

In some implementations, the image sensing device may include a first floating diffusion region and a second floating diffusion region. The first floating diffusion region may be spaced apart from the gate of the first transfer transistor, may be disposed in the semiconductor substrate, and may be adjacent to the second surface. The second floating diffusion region may be spaced apart from the gate of the second transfer transistor, may be disposed in the semiconductor substrate, and may be adjacent to the second surface.

In some implementations, the image sensing device may further include a metal interconnect layer configured to contact each of the first floating diffusion region and the second floating diffusion region while being located outside the semiconductor substrate, wherein the metal interconnect layer electrically connects the first floating diffusion region and the second floating diffusion region to each other.

In some implementations, the image sensing device may further include a pixel isolation structure recessed from the first surface of the semiconductor substrate corresponding to the gap region toward an inside of the semiconductor substrate.

In some implementations, the first photoelectric conversion element and the second photoelectric conversion element are configured to share the floating diffusion region.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a plan view illustrating an example of a portion of a pixel array shown in FIG. 1 based on some implementations of the disclosed technology.

FIG. 3 is a circuit diagram illustrating an example of a unit pixel shown in FIG. 2 based on some implementations of the disclosed technology.

FIG. 4 is a plan view illustrating an example of a first embodiment of the unit pixel shown in FIG. 2 based on some implementations of the disclosed technology.

FIG. 5 is a plan view illustrating an example of a second embodiment of the unit pixel shown in FIG. 2 based on some implementations of the disclosed technology.

FIG. 6 is a plan view illustrating an example of a third embodiment of the unit pixel shown in FIG. 2 based on some implementations of the disclosed technology.

FIG. 7 is a plan view illustrating an example of a fourth embodiment of the unit pixel shown in FIG. 2 based on some implementations of the disclosed technology.

FIG. 8 is a cross-sectional view illustrating an example of the unit pixel taken along the line A-A′ of FIGS. 4 to 6 based on some implementations of the disclosed technology.

FIG. 9 is a cross-sectional view illustrating an example of the unit pixel taken along the line B-B′ of FIG. 7 based on some implementations of the disclosed technology.

FIG. 10 is a cross-sectional view illustrating an example of the unit pixel taken along the line C-C′ of FIG. 4 based on some implementations of the disclosed technology.

FIG. 11 is a cross-sectional view illustrating an example of the unit pixel taken along the line D-D′ of FIGS. 4 to 7 based on some implementations of the disclosed technology.

FIG. 12 is a cross-sectional view illustrating an example of the unit pixel taken along the line E-E′ of FIGS. 4 to 7 based on some implementations of the disclosed technology.

### DETAILED DESCRIPTION

This patent document provides implementations and examples of an image sensing device including a source follower transistor that may be used in configurations to substantially address one or more technical or engineering issues and to mitigate limitations or disadvantages encountered in some image sensing devices in the art. Some implementations of the disclosed technology relate to an image sensing device including a structure capable of guaranteeing a larger gate region of a source follower transistor to reduce the amount of noise. In recognition of the issues above, the image sensing device can reduce the amount of noise to be generated in electrical signals output from pixels by securing a large gate region of a source follower transistor.

Reference will now be made in detail to some embodiments of the disclosed technology, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

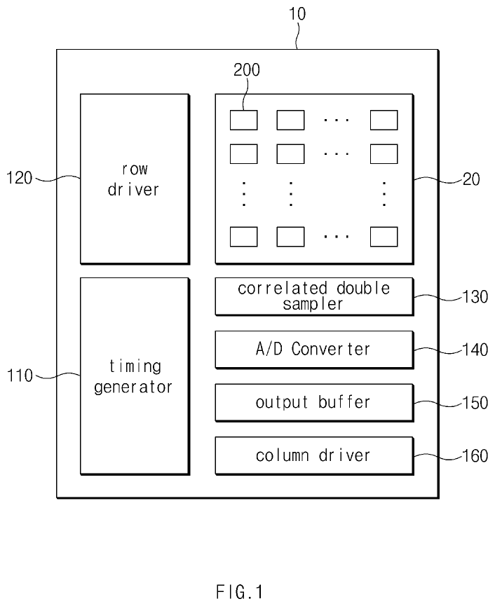

FIG. 1 is a block diagram illustrating an example of an image sensing device 100 based on some implementations of the disclosed technology.

Referring to FIG. 1, the image sensing device 100 based on some implementations of the disclosed technology may include a timing controller 110, a row driver 120, a pixel array 20, a correlated double sampler (CDS) 130, an analog-to-digital converter (ADC) 140, an output buffer 150, and a column driver 160. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The timing controller 110 may provide timing signals and control signals to at least one of the row driver 120, the correlated double sampler (CDS) 130, the ADC 140, the output buffer 150, and the column driver 160.

The row driver 120 may activate the pixel array 20 to perform specific operations on pixels included in a corresponding row based on the timing and control signals received from the timing controller 110.

In some implementations, the row driver 120 may select at least one pixel arranged in at least one row of the pixel array 20, and may provide the selected pixel with a control signal for performing a specific operation. The row driver 120 may generate a row selection signal to select at least one row from among a plurality of rows. When the row driver 120 selects a specific row from among the plurality of rows to perform a specific operation, the row driver 120 may not perform the specific operation on a row adjacent to the selected specific row.

The pixels of the row selected by the row driver 120 may sequentially transfer analog reference signals and image signals to the correlated double sampler (CDS) 130. The reference signal may be an electrical signal provided to the CDS 130 when a floating diffusion region of each pixel is reset to a power-supply voltage VDD. The image signal may be an electrical signal provided to the CDS 130 when photocharges generated by each pixel are accumulated in the floating diffusion region (FD) region.

The reference signal may be a signal indicating unique pixel noise of each pixel, and the reference signal and the image signal may be collectively referred to as a pixel signal as necessary.

The pixel array 20 may include a plurality of pixels arranged in a plurality of rows and a plurality of columns and supported by a substrate. The plurality of pixels may be connected to the row driver 120 through a plurality of row lines extending in the row direction. The plurality of pixels may be connected to the CDS 130 through a plurality of column lines extending in the column direction. The pixel array 20 may include at least one pixel 200 arranged in the row direction and the column direction. For example, the pixel array 20 may be arranged in a two-dimensional (2D) pixel array in which a plurality of unit pixels includes rows and columns.

The plurality of unit pixels 200 included in the pixel array may convert optical signals into electrical signals, and may be connected to a specific internal pixel circuit.

The pixel array 20 may receive a pixel control signal including a row selection signal, a pixel reset signal, a row transfer signal, etc. from the row driver 120. At least one pixel included in the row that is selected by the row driver 120 according to the pixel control signal may perform a specific operation in response to the row selection signal, the pixel reset signal, and the row transfer signal.

The CDS 130 may receive the reference signal and the image signal, each of which corresponds to the columns of the pixel array 20, and may sample levels of the reference signal and the image signal. In the image sensing device designed to use CMOS(s), the CDS 130 may sample a pixel signal twice to remove a difference between these two samples, and may perform correlated double sampling to remove undesired offset values of pixels such as fixed noise. For example, the CDS 130 may compare pixel output voltages obtained before and after photocharges generated by incident light are accumulated in the floating diffusion region to remove undesired offset values, so that the pixel output voltages based on the incident light can be measured.

The CDS 130 may transmit reference signals and image signals, which are generated in columns based on a timing signal and a control signal of the timing controller 110, to the ADC 140 as CDS signals.

The ADC 140 may convert analog CDS signals received from the CDS 130 into digital signals, and may output the resultant digital signals.

The output buffer 150 may temporarily hold and output digital signals provided from the ADC 140.

The column driver 160 may select columns from the output buffer 150 based on a timing signal and a control signal of the timing controller 110, and may control the temporarily held digital signals to be output according to the selection order.

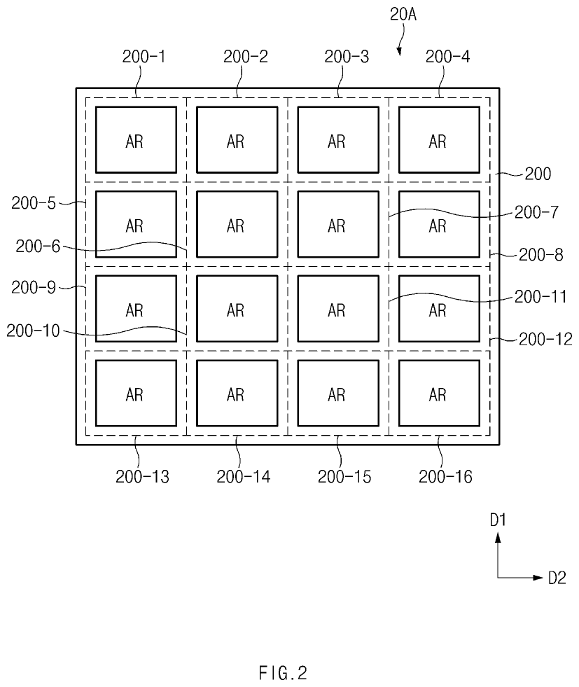

FIG. 2 is a plan view illustrating an example of a portion of the pixel array shown in FIG. 1 based on some implementations of the disclosed technology.

Referring to FIG. 2, a pixel array 20A may correspond to a portion of the pixel array 20 shown in FIG. 1. The pixel array 20A may include a plurality of unit pixels arranged adjacent each other. For example, the plurality of unit pixels included in the pixel array 20A may be arranged in an (M×N) matrix structure. Here, ‘m’ may denote the number of lines in the row direction D2, and may be an integer equal to or greater than 2. In addition, ‘n’ may denote the number of lines in the column direction D1, and may be an integer equal to or greater than 2. FIG. 2 is a schematic diagram illustrating an example structure in which first to sixteenth unit pixels (200-1˜200-16) are arranged in a (4×4) matrix structure including four row lines (m=4) and four column lines (n=4).

Each of the first to sixteenth unit pixels (200-1˜200-16) may include an active region (AR) and a pixel isolation structure 210. The adjacent active regions (ARs) may be isolated from each other by a pixel isolation structure 210.

The plurality of active regions (ARs) may be supported by or included in a semiconductor substrate, and the semiconductor substrate may include, for example, silicon (Si). For example, the active region (AR) may include a photoelectric conversion element that can generate photocharges in response to incident light when external light is incident upon the semiconductor substrate including the active regions (ARs).

The pixel isolation structure 210 may isolate the active regions (AR) of each of the first to sixteenth unit pixels (200-1˜200-16) from one another. The pixel isolation structure 210 may include, for example, a grid structure. The pixel isolation structure 210 may optically isolate the active regions (ARs) of adjacent unit pixels (e.g., the first unit pixel 200-1 and the second unit pixel 200-2) from each other, and the pixel isolation structure 210 may include an insulation material (e.g., polysilicon, etc.). The pixel isolation structure 210 may be disposed over the semiconductor substrate while being formed in a recessed structure that is recessed from either a first surface of the semiconductor substrate or a second surface facing or opposite to the first surface. In the semiconductor substrate, the first surface may refer to a back surface upon which light is incident from the outside, and the second surface may refer to a front surface. In some implementations, the pixel isolation structure 210 may have a structure that is recessed from the front surface toward the inside of the semiconductor substrate.

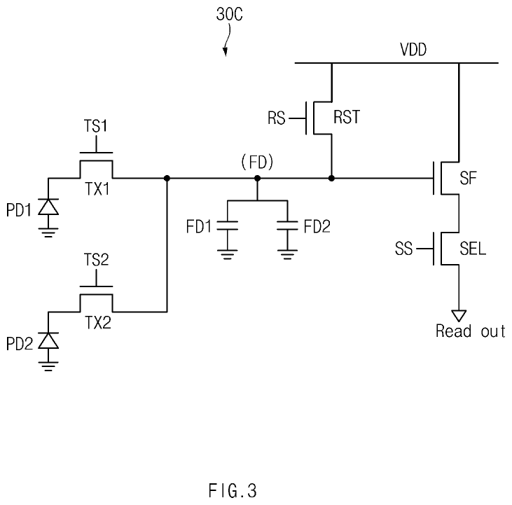

FIG. 3 is a circuit diagram illustrating an example of the unit pixel shown in FIG. 2 based on some implementations of the disclosed technology.

Referring to FIG. 3, the equivalent circuit 30C of the unit pixel may include a first photoelectric conversion element (PD1), a second photoelectric conversion element (PD2), a first transfer transistor (TX1), a second transfer transistor (TX2), a first floating diffusion region (FD1), a second floating diffusion region (FD2), a reset transistor (RST), a source follower transistor (SF), and a selection transistor (SEL).

The first photoelectric conversion element (PD1) and the second photoelectric conversion element (PD2) may generate and accumulate photocharges corresponding to the intensity of incident light through photoelectric conversion of the incident light. For example, each of the first photoelectric conversion element (PD1) and the second photoelectric conversion element (PD2) may be implemented as a photodiode, a phototransistor, a photogate, a pinned photodiode or a combination thereof. FIG. 3 is a circuit diagram illustrating an example circuit in which the first photoelectric conversion element (PD1) and the second photoelectric conversion element (PD2) are implemented as photodiodes.

The first floating diffusion region (FD1) and the second floating diffusion region (FD2) may receive photocharges accumulated in the first photoelectric conversion element (PD1) and photocharges accumulated in the second photoelectric conversion element (PD2), respectively, and may store the received photocharges, respectively. In the example as shown in FIG. 3, the first floating diffusion region (FD1) and the second floating diffusion region (FD2) may be modeled as capacitors that can be configured to have respective capacitances. The first floating diffusion region (FD1) and the second floating diffusion region (FD2) may be electrically connected in parallel to each other. The first floating diffusion region (FD1) and the second floating diffusion region (FD2) that are connected in parallel to each other may be included in one floating diffusion region (FD).

The first photoelectric conversion element (PD1) and the second photoelectric conversion element (PD2) may share one floating diffusion region (FD), and one floating diffusion region (FD) may provide capacitance equal to the sum of the capacitance of the first floating diffusion region (FD1) and the capacitance of the second floating diffusion region (FD2).

The first transfer transistor (TX1) may be a transistor having one terminal that is connected to the first photoelectric conversion element (PD1) and the other terminal that is connected to the floating diffusion region (FD). A first transfer signal (TS1) may be transmitted to the first transfer transistor (TX1). A voltage corresponding to a signal level of the first transfer signal (TS1) may be applied to a gate of the first transfer transistor (TX1), and when a voltage equal to or greater than a threshold voltage is applied to the gate of the first transfer transistor (TX1), the photocharges accumulated in the first photoelectric conversion element (PD1) may be transferred to the floating diffusion region (FD).

The second transfer transistor (TX2) may be a transistor having one terminal that is connected to the second photoelectric conversion element (PD2) and the other terminal that is connected to the floating diffusion region (FD). A second transfer signal (TS2) may be transmitted to the second transfer transistor (TX2). A voltage corresponding to a signal level of the second transfer signal (TS2) may be applied to a gate of the second transfer transistor (TX2), and when a voltage equal to or greater than a threshold voltage is applied to the gate of the second transfer transistor (TX2), the photocharges accumulated in the second photoelectric conversion element (PD2) may be transferred to the floating diffusion region (FD).

The reset transistor (RST) may be a transistor having one terminal that is connected to the floating diffusion region (FD) and the other terminal that is connected to a power-supply voltage (VDD). A reset signal (RS) may be transmitted to the reset transistor (RST). A voltage corresponding to a signal level of the reset signal (RS) may be applied to a gate of the reset transistor (RST), and when a voltage equal to or greater than a threshold voltage is applied to the gate of the reset transistor (RST), the photocharges stored in the floating diffusion region (FD) may be removed from the floating diffusion region (FD). Each of the reset transistor (RST) and the first and second transfer transistors (TX1, TX2) may be in a turned-ON state or turned-OFF state. The turned-ON state may refer to a case when a voltage equal to or greater than the threshold voltage is applied to a corresponding one of the reset transistor (RST) and the first and second transfer transistors (TX1, TX2). The turned-OFF state may refer to the case when a voltage less than the threshold voltage is applied to a corresponding one of the reset transistor (RST) and the first and second transfer transistors (TX1, TX2). When each of the reset transistor (RST) and the first or second transfer transistor (TX1 or TX2) are in the turned-ON state, the photocharges accumulated in the first or second photoelectric conversion element (PD1 or PD2) may be removed, and the photocharges stored in the floating diffusion region (FD) may also be removed.

One terminal of the source follower transistor (SF) may be connected to the power-supply voltage (VDD), and the other terminal of the source follower transistor (SF) may be connected to the selection transistor (SEL). A voltage generated by the photocharges stored in the floating diffusion region (FD) may be applied to a gate of the source follower transistor (SF). The source follower transistor (SF) may output an electrical signal in response to the voltage generated by the photocharges stored in the floating diffusion region (FD).

One terminal of the selection transistor (SEL) may be connected to the source follower transistor (SF), and the other terminal of the selection transistor (SEL) may be connected to an output terminal. A selection signal (SS) may be transmitted to the selection transistor (SEL). A voltage corresponding to a signal level of the selection signal (SS) may be applied to a gate of the selection transistor SEL, and when a voltage equal to or greater than a threshold voltage is applied to the gate of the selection transistor (SEL) (i.e., the selection transistor (SEL) transitions to the turned-ON state), an electrical signal amplified by the source follower transistor (SF) may be output to the output terminal. The output terminal may transmit the electrical signal output to the output terminal to the correlated double sampler (CDS) 130 of FIG. 1.

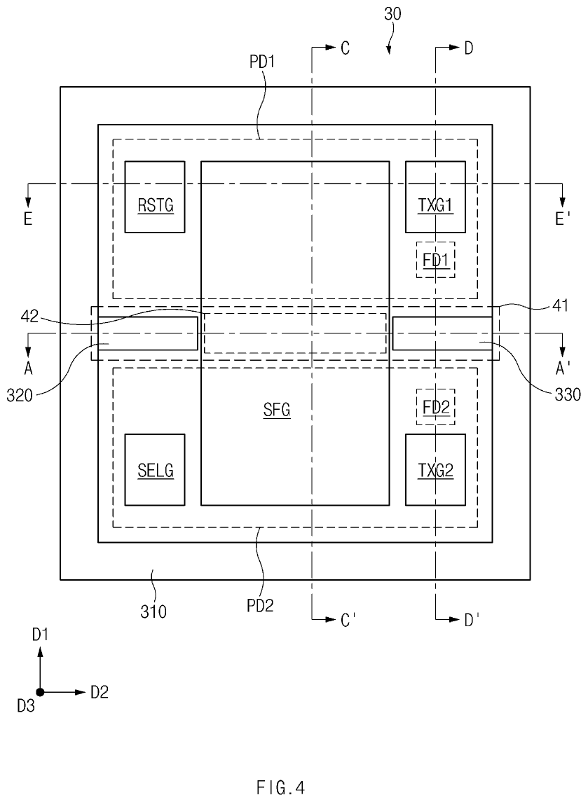

FIG. 4 is a plan view illustrating an example of a first embodiment of the unit pixel shown in FIG. 2 based on some implementations of the disclosed technology.

Referring to FIGS. 2 to 4, the unit pixel 30 of FIG. 4 may be an example of the first to sixteenth unit pixels (200-1˜200-16) of FIG. 2. The unit pixel 30 may include a first pixel isolation structure 310, a first photoelectric conversion element (PD1), a second photoelectric conversion element (PD2), a first floating diffusion region (FD1), a second floating diffusion region (FD2), a gate (TXG1) of a first transfer transistor (TX1), a gate (TXG2) of a second transfer transistor (TX2), a gate (RSTG) of a reset transistor (RST), a gate (SFG) of a source follower transistor (SF), and a gate (SELG) of a selection transistor (SEL). The unit pixel 30 may further include a second pixel isolation structure 320 and a third pixel isolation structure 330. The first pixel isolation structure 310 may be disposed outside the unit pixel 30. The first pixel isolation structure 310 may be provided and supported by the semiconductor substrate, for example, being disposed inside the semiconductor substrate. The semiconductor substrate may include a first surface upon which light is incident, and a second surface facing or opposite to the first surface. The first pixel isolation structure 310 may include a structure recessed from the second surface. The first pixel isolation structure 310 may include at least one of polysilicon or silicon oxide. For example, the first pixel isolation structure 310 may include a polysilicon or a silicon oxide. For example, the first pixel isolation structure 310 may include both polysilicon and a silicon oxide. The first pixel isolation structure 310 may be disposed between the unit pixel 30 and at least one adjacent unit pixel arranged adjacent to the unit pixel 30 (not shown) and configured to optically isolate the unit pixel 30 and at least one adjacent unit pixel from each other. For example, the first pixel isolation structure 310 may prevent crosstalk between the unit pixel 30 and the adjacent unit pixel such that light incident upon the unit pixel 30 can be prevented from being incident upon the adjacent unit pixel.

The second pixel isolation structure 320 may be arranged to extend in a second direction D2 within a first gap region 41 indicating a space between the first photoelectric conversion element (PD1) and the second photoelectric conversion element (PD2). The second pixel isolation structure 320 may be disposed to contact the first pixel isolation structure 310. The second pixel isolation structure 320 may include a structure recessed from the second surface of the semiconductor substrate. The second pixel isolation structure 320 may include substantially the same material as the first pixel isolation structure 310.

The third pixel isolation structure 330 may be arranged to extend in the second direction D2 within the first gap region 41. The third pixel isolation structure 330 may be arranged to be spaced apart from the second pixel isolation structure 320. The third pixel isolation structure 330 may be arranged to contact the first pixel isolation structure 310 at an opposite side of a region in which the second pixel isolation structure 320 is in contact with the first pixel isolation structure 310. The third pixel isolation structure 330 may include a structure recessed from the second surface of the semiconductor substrate. The third pixel isolation structure 330 may include substantially the same material as the first pixel isolation structure 310.

The second pixel isolation structure 320 and the third pixel isolation structure 330 may prevent crosstalk of incident light between the first photoelectric conversion element PD1 and the second photoelectric conversion element PD2.

Each of the first photoelectric conversion element (PD1) and the second photoelectric conversion element (PD2) may generate and accumulate photocharges corresponding to the intensity of incident light. The first photoelectric conversion element (PD1) and the second photoelectric conversion element (PD2) may be spaced apart from each other in a first direction D1. Each of the first photoelectric conversion element (PD1) and the second photoelectric conversion element (PD2) may be arranged to occupy as large a region as possible to increase a fill-factor indicating light reception efficiency. For example, each of the first photoelectric conversion element (PD1) and the second photoelectric conversion element (PD2) may be implemented as a photodiode, a phototransistor, a photogate, a pinned photodiode or a combination thereof.

When the first photoelectric conversion element (PD1) and the second photoelectric conversion element (PD2) are implemented as photodiodes, each of the first photoelectric conversion element (PD1) and the second photoelectric conversion element (PD2) may be a region in which ions are implanted into the semiconductor substrate. In some implementations, the photodiode may include a structure in which a plurality of doped regions is stacked.

The first gap region 41 may be or include a space disposed between the first photoelectric conversion element (PD1) and the second photoelectric conversion element (PD2). More specifically, the first gap region 41 may refer to a space in which both ends of the first gap region 41 arranged in the first direction D1 within the semiconductor substrate respectively contact the first photoelectric conversion element (PD1) and the second photoelectric conversion element (PD2), and both ends of the first gap region 41 arranged in the second direction D2 within the semiconductor substrate are in contact with the first pixel isolation structure 310. The structure shown in FIG. 4 illustrating that the width of the first gap region 41 in the first direction D1 is smaller than a separation distance between the first photoelectric conversion element (PD1) and the second photoelectric conversion element (PD2) and the width of the first gap region 41 in the second direction D2 is larger than a separation distance between both ends of the first pixel isolation structure 310 may be constructed only to prevent overlap between the lines shown in FIG. 4. The width of the first gap region 41 in the first direction D1 may be equal to a separation distance between the first photoelectric conversion element (PD1) and the second photoelectric conversion element (PD2), and the width of the first gap region 41 in the second direction D2 may be equal to a separation distance between both ends of the first pixel isolation structure 310.

A second gap region 42 may be or include a space located inside the semiconductor substrate that is surrounded by the first photoelectric conversion element (PD1), the second photoelectric conversion element (PD2), the second pixel isolation structure 320, and the third pixel isolation structure 330. The reason why the second gap region 42 shown in FIG. 4 is configured such that the width of the second gap region 42 in the first direction D1 is smaller than a separation distance between the first photoelectric conversion element (PD1) and the second photoelectric conversion element (PD2) and the width of the second gap region 42 in the second direction D2 is smaller than a separation distance between the second pixel isolation structure 320 and the third pixel isolation structure 330 is to prevent overlap between the lines shown in FIG. 4. The width of the second gap region 42 in the first direction D1 may be equal to a separation distance between the first photoelectric conversion element (PD1) and the second photoelectric conversion element (PD2), and the width of the second gap region 42 in the second direction D2 may be equal to a separation distance between the second pixel isolation structure 320 and the third pixel isolation structure 330.

In some implementations, the gate (SFG) of the source follower transistor (SF) may be disposed on the second surface of the semiconductor substrate including the second gap region 42. The gate of the source follower transistor SF may be disposed to overlap the first photoelectric conversion element (PD1) and the second photoelectric conversion element (PD2). As the region in which the gate of the source follower transistor (SF) overlaps the first and second photoelectric conversion elements (PD1, PD2) increases in width, noise of the electrical signal output from the source follower transistor (SF) can be reduced.

The gate (SFG) of the source follower transistor (SF) may overlap the second gap region 42, and may extend in the first direction D1. For example, the gate (SFG) of the source follower transistor (SF) may be formed in a rectangular shape that has a vertical length that maximally extends in the first direction D1 within a range not contacting the first pixel isolation structure 310 and a horizontal length equal to the width of the second gap region 42 in the second direction D2. In another example, the gate (SFG) of the source follower transistor (SF) may have a larger width in the second direction D2 than the second gap region 42 arranged in the second direction D2 within a region in which the gate (SFG) of the source follower transistor (SF) overlaps the first or second photoelectric conversion element PD1 or PD2. The scope of the disclosed technology is not limited to the above-described two embodiments, and other implementations are also possible. For example, the image sensing device based on some implementations of the disclosed technology can be configured such that the gate (SFG) structure of the source follower transistor (SF) extends in the first direction D1 while being disposed over the second surface of the semiconductor substrate corresponding to the second gap region 42, regardless of the width of the gate (SFG) of the source follower transistor (SF). For example, in some implementations, the width of the gate (SFG) of the source follower transistor (SF) can be varied.

If the region of the gate (SFG) of the source follower transistor (SF) increases in size, noise of the unit pixel 30 may be reduced. More specifically, the source follower transistor (SF) may amplify a potential of the first floating diffusion region (FD1) storing photocharges generated by the first photoelectric conversion element (PD1) and a potential of the second floating diffusion region (FD2) storing photocharges generated by the second photoelectric conversion element (PD2). As the gate (SFG) of the source follower transistor (SF) increases in size, noise of each pixel can be reduced. Hereinafter, a detailed description thereof will be given with reference to Equation 1 below.

$${S}_{Vg} = {( \frac{q}{{C}_{ox}} )}^{2} \frac{{kTN}_{T} ( {E}_{f} )}{γ fWL} ∝ \frac{1}{{C}_{ox}^{2}} \qquad [ Equation 1 ]$$

In Equation 1, ‘S_{vg}’ denotes a noise voltage power, ‘N_{T}’ denotes a trap state density, ‘Cₒₓ’ denotes a capacitance of an oxide layer, ‘W’ denotes a width of the gate of a transistor, ‘L’ denotes a length of the gate of the transistor, and ‘WL’ corresponding to ‘W×L’ corresponds to an area (region) of the gate of the transistor. Since the noise power (S_{vg}) and the area of the gate region (WL) of the transistor are inversely proportional to each other, noise may be reduced as the gate region of the transistor increases in size. Equation 1 above may also be applied to the source follower transistor (SF). As the region of the gate (SFG) of the source follower transistor (SF) increases in size, noise of the electrical signal output through the selection transistor (SEL) may be reduced. The image sensing device based on some implementations of the disclosed technology can guarantee a larger region of the gate (SFG) of the source follower transistor (SF) within the unit pixel having a limited size through a specific structure in which the source follower transistor (SF) is not allocated to each of the first and second photoelectric conversion elements (PD1, PD2) and the first photoelectric conversion element (PD1) and the second photoelectric conversion element (PD2) share only one source follower transistor (SF).

For example, the first floating diffusion region (FD1) may be arranged to overlap the first photoelectric conversion element (PD1) in a third direction D3. In another example, the first floating diffusion region (FD1) may be arranged not to overlap the first photoelectric conversion element (PD1) when viewed in the third direction D3. As a light reception region of the first photoelectric conversion element (PD1) increases in size, photoelectric conversion efficiency of the first photoelectric conversion element (PD1) can be improved. One embodiment in which the first floating diffusion region (FD1) and the first photoelectric conversion element (PD1) overlap each other in the third direction D3 will hereinafter be described with reference to the attached drawings.

For example, the second floating diffusion region (FD2) may be arranged to overlap the second photoelectric conversion element (PD2) in the third direction D3. In another example, the second floating diffusion region (FD2) may be spaced apart from the second photoelectric conversion element (PD2) when viewed in the third direction D3. One embodiment in which the second floating diffusion region (FD2) and the second photoelectric conversion element (PD2) overlap each other in the third direction D3 will hereinafter be described with reference to the attached drawings.

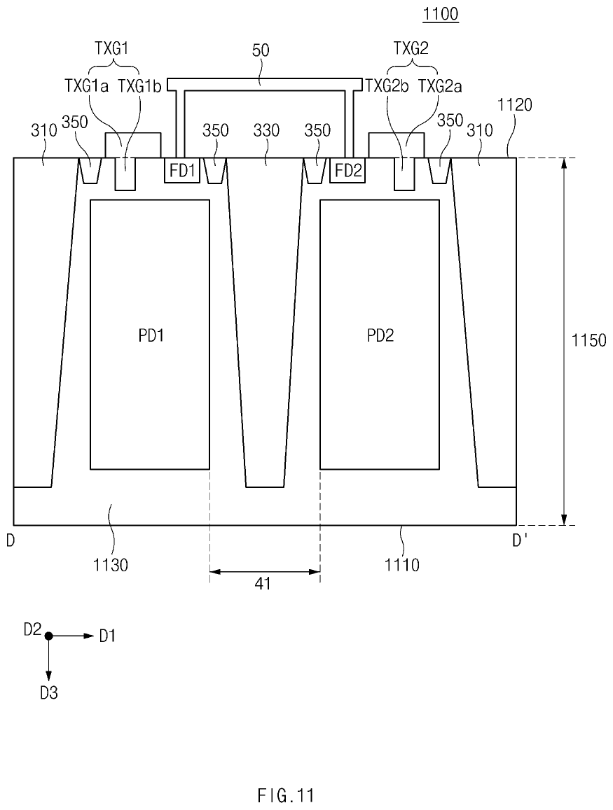

The second floating diffusion region (FD2) may be arranged to be spaced apart from the first floating diffusion region (FD1) when viewed in the plan view of FIG. 4, but may be electrically connected to the first floating diffusion region (FD1) through a predetermined metal interconnect layer. The predetermined metal interconnect layer will be described later with reference to FIG. 11.

FIG. 4 shows the implementation in which the floating diffusion region (FD) is arranged such that the first floating diffusion region (FD1) and the second floating diffusion region (FD2) are isolated from each other and the first floating diffusion region (FD1) and the second floating diffusion region (FD2) are electrically connected to each other through a predetermined metal interconnect layer. Without being limited to the implementations as shown in FIG. 4, other implementations are also possible. For example, in some implementations, only one floating diffusion region may be disposed without using the predetermined metal interconnect layer. For example, the one floating diffusion region may be disposed between a gate (TXG1) of the first transfer transistor (TX1) and a gate (TXG2) of the second transfer transistor (TX2).

Each of the gate (TXG1) of the first transfer transistor (TX1) and the gate (TXG2) of the second transfer transistor (TX2) may be spaced apart from the gate (SFG) of the source follower transistor SF, so that the gate (TXG1) of the first transfer transistor (TX1) and the gate (TXG2) of the second transfer transistor (TX2) spaced apart from each other may be disposed on the second surface of the semiconductor substrate. The gate (TXG1) of the first transfer transistor (TX1) may overlap the first photoelectric conversion element (PD1) in the third direction D3, and the gate (TXG2) of the second transfer transistor (TX2) may overlap the second photoelectric conversion element (PD2) in the third direction D3. The gate (TXG1) of the first transfer transistor (TX1) may overlap or be spaced apart from the first floating diffusion region (FD1) in the third direction D3, and the gate (TXG2) of the second transfer transistor (TX2) may overlap or be spaced apart from the second floating diffusion region (FD2) in the third direction D3. As can be seen from FIG. 4, the gate (TXG1) of the first transfer transistor (TX1) and the first floating diffusion region (FD1) may be arranged to be spaced apart from each other, and the gate (TXG2) of the second transfer transistor (TX2) and the second floating diffusion region (FD2) may be arranged to be spaced apart from each other.

A gate (RSTG) of the reset transistor (RST) may be disposed on the second surface of the semiconductor substrate while being spaced apart from the gate (SFG) of the source follower transistor (SF). The gate (RSTG) of the reset transistor (RST) may be disposed to overlap the first photoelectric conversion element (PD1). The gate (RSTG) of the reset transistor (RST) may correspond to a region in which a voltage is applied to the reset transistor (RST).

A gate (SELG) of the selection transistor (SEL) may be spaced apart from the gate (SFG) of the source follower transistor (SF), and may be disposed on the second surface of the semiconductor substrate. The gate (SELG) of the selection transistor SEL may be disposed to overlap the second photoelectric conversion element (PD2). The gate (SELG) of the selection transistor (SEL) may correspond to a region in which a voltage is applied to the selection transistor (SEL).

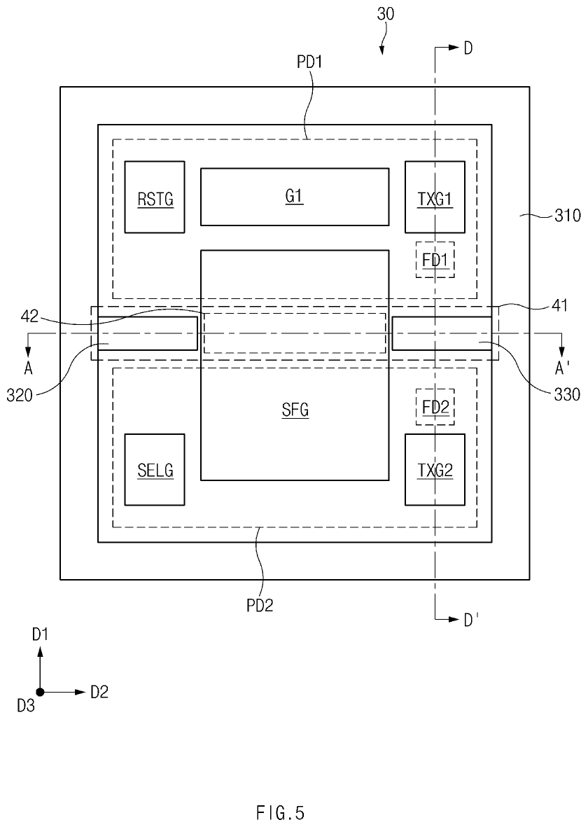

FIG. 5 is a plan view illustrating an example of a second embodiment of the unit pixel shown in FIG. 2 based on some implementations of the disclosed technology.

In the below, characteristics of the unit pixel of FIG. 5, which are different from those of the unit pixel of FIG. 4, will be mainly described.

Referring to FIG. 5, a gate (G1) of the first transistor may be disposed on the second surface of the semiconductor substrate while being spaced apart from the gate (SFG) of the source follower transistor within the unit pixel 30. The gate (G1) of the first transistor may be disposed to overlap the first photoelectric conversion element (PD1). Although FIG. 5 shows an embodiment in which the gate (G1) of the first transistor overlaps the first photoelectric conversion element (PD1), other implementations are also possible. For example, in some implementations, the gate (G1) of the first transistor may also overlap the second photoelectric conversion element (PD2). The gate (G1) of the first transistor may correspond to a region in which a voltage is applied to the first transistor. The first transistor may be, for example, a drain transistor or a dual conversion gain (DCG) transistor.

When the first transistor is a drain transistor, one terminal of the drain transistor may be connected to the first photoelectric conversion element (PD1) or the second photoelectric conversion element (PD2), and the other terminal of the drain transistor may be connected to the power-supply voltage (VDD). When a voltage equal to or greater than a threshold voltage is applied to the gate of the drain transistor, photocharges generated and accumulated in the first photoelectric conversion element (PD1) or the second photoelectric conversion element (PD2) may be removed.

When the first transistor is a DCG transistor, when a voltage equal to or greater than the threshold voltage is applied to a gate of the DCG transistor, capacitance of either the first floating diffusion region (FD1) or the second floating diffusion region (FD2) may increase. The amount of photocharges accumulated in the first floating diffusion region (FD1) and the second floating diffusion region (FD2) may be proportional to capacitance and voltage. As the capacitance increases, the voltage to be applied to the source follower transistor may decrease. As the capacitance decreases, the voltage to be applied to the source follower transistor may increase. Therefore, when a voltage equal to or greater than the threshold voltage is applied to the gate of the DCG transistor, the voltage to be applied to the source follower transistor may decrease, so that the source follower transistor may have a low conversion gain. Then, when a voltage less than the threshold voltage is applied to the gate of the DCG transistor, a relatively high voltage may be applied to the source follower transistor, and the source follower transistor may have a high conversion gain.

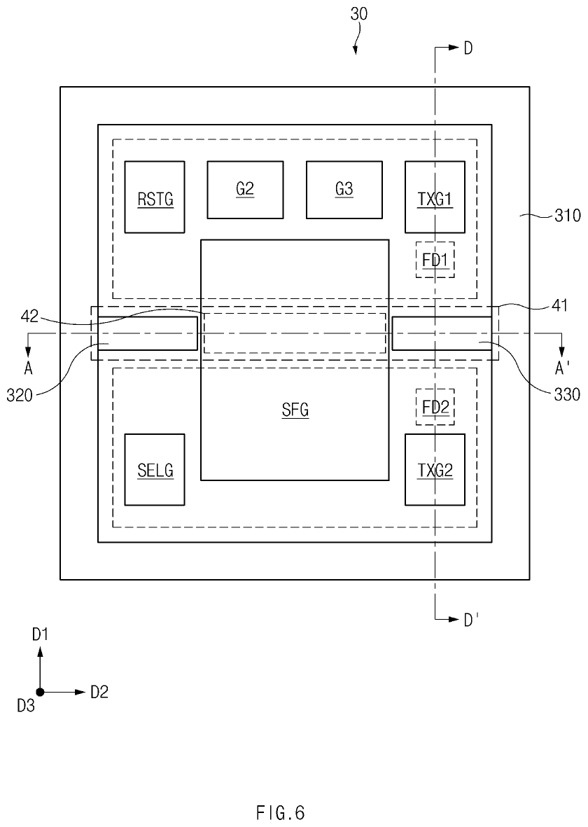

FIG. 6 is a plan view illustrating an example of a third embodiment of the unit pixel shown in FIG. 2 based on some implementations of the disclosed technology.

In the below, characteristics of the unit pixel of FIG. 6, which are different from those of the unit pixel of FIG. 4, will be mainly described.

Referring to FIG. 6, the gate (G2) of the second transistor may be spaced apart from the gate (SFG) of the source follower transistor (SF) within the unit pixel 30, and may be disposed on the second surface of the semiconductor substrate. The second transistor may be a drain transistor or a DCG transistor.

The gate (G3) of the third transistor may be disposed on the second surface of the semiconductor substrate at a position where the gate (G3) of the third transistor is spaced apart from each of the gate (SFG) of the source follower transistor (SF) and the gate (G2) of the second transistor within the unit pixel 30. The third transistor may be a DCG transistor.

In one embodiment in which the second transistor is a drain transistor and the third transistor is a DCG transistor, a process of resetting photocharges of the first photoelectric conversion element (PD1) or the second photoelectric conversion element (PD2) may be performed by the drain transistor. As can be seen from FIG. 5, when the magnitude of a voltage that can be applied to the gate of the DCG transistor is adjusted according to the ON-OFF states of the DCG transistor, double gain conversion of the source follower transistor can be implemented.

One embodiment in which the second transistor is a first DCG transistor and the third transistor is a second DCG transistor may be implemented such that triple gain conversion of the source follower transistor can be performed according to the ON-OFF states of each of the first DCG transistor and the second DCG transistor. For example, when both the first DCG transistor and the second DCG transistor are turned on (when a voltage equal to or greater than the threshold voltage is applied to each of the first and second DCG transistors), first gain conversion may be performed. Then, when any one of the first DCG transistor and the second DCG transistor is turned on or the other one is turned off, second gain conversion may be performed, and when both the first DCG transistor and the second DCG transistor are turned off, third gain conversion may be performed.

At the same time, one embodiment of the disclosed technology may provide the image sensing device that can maximally secure the region of the gate (SFG) of the source follower transistor within a range in which the gate (SFG) of the source follower transistor is spaced apart from the gate (G2) of the second transistor and the gate (G3) of the third transistor, and can thus reduce the amount of noise of the electrical signal capable of being output from the source follower transistor.

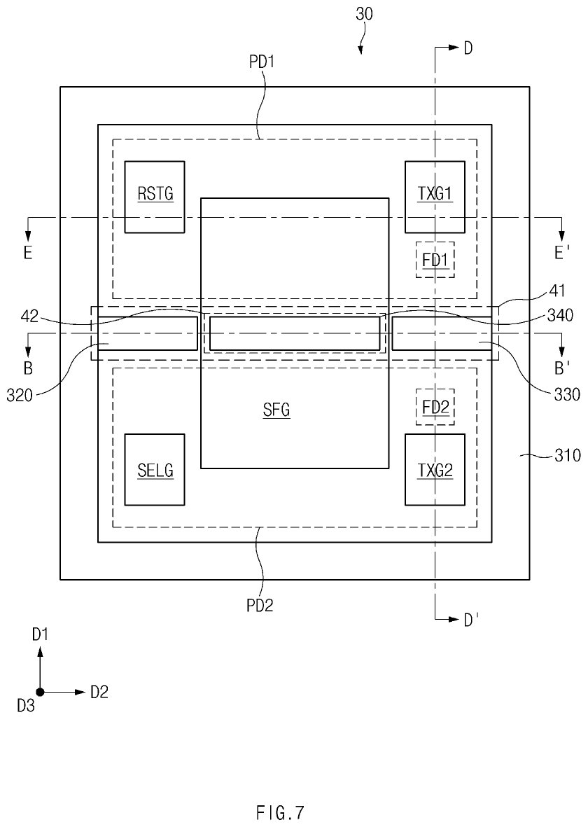

FIG. 7 is a plan view illustrating an example of a fourth embodiment of the unit pixel shown in FIG. 2 based on some implementations of the disclosed technology.

In the below, characteristics of the unit pixel of FIG. 7, which are different from those of the unit pixel of FIG. 4, will be mainly described.

In the below, characteristics of the unit pixel 30 of FIG. 7 may further include a fourth pixel isolation structure 340 in addition to the constituent elements of the unit pixel 30 of FIG. 4.

The fourth pixel isolation structure 340 may be disposed in the second gap region 42. The fourth pixel isolation structure 340 may include a recessed structure on the first surface of the semiconductor substrate. The fourth pixel isolation structure 340 may include at least one of polysilicon and silicon oxide. The fourth pixel isolation structure 340 may be configured to optically isolate the first photoelectric conversion element (PD1) and the second photoelectric conversion element (PD2) from each other, thereby preventing crosstalk between the first photoelectric conversion element (PD1) and the second photoelectric conversion element (PD2).

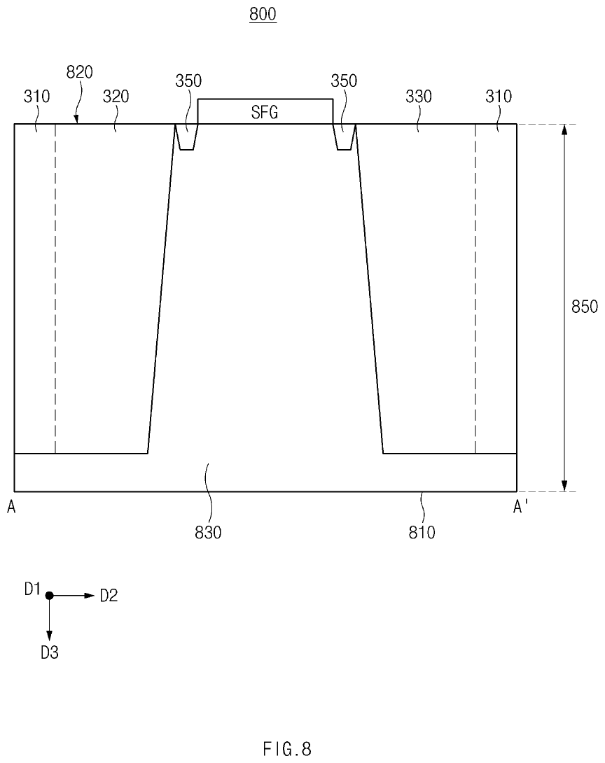

FIG. 8 is a cross-sectional view illustrating an example of the unit pixel taken along the line A-A′ of FIGS. 4 to 6 based on some implementations of the disclosed technology.

Referring to FIGS. 4 and 8, a first cross-section 800 of the unit pixel 30 taken along the line A-A′ of FIG. 4 may be an example of a cross-section of the unit pixel 30 taken along the line A-A′. Although the first cross-section 800 is a cross-section taken along the line A-A′ of FIG. 4, a cross-section of another portion (i.e., a portion taken along a line crossing the unit pixel 30 in the second direction D2 between the first photoelectric conversion element PD1 and the second photoelectric conversion element PD2) taken along the line A-A′ may also have substantially the same structure as the first cross-section 800.

The first cross-section 800 of the unit pixel 30 may include a semiconductor substrate 850, an epitaxial region 830, a first pixel isolation structure 310, a second pixel isolation structure 320, a third pixel isolation structure 330, a pixel insulation structure 350, and a gate (SFG) of the source follower transistor.

The semiconductor substrate 850 may include a first surface 810 and a second surface 820 facing or opposite to the first surface 810. The semiconductor substrate 850 may include a silicon material. The first surface 810 may be a back surface upon which light is incident. The second surface 820 may be a front surface. One or more optical filters (not shown) for transmitting light of a specific color may be disposed on the first surface 810.

In some implementations, the first pixel isolation structure 310 may be disposed in a recessed structure that is recessed in the third direction D3 from the second surface 820. The first pixel isolation structure 310 may be disposed at both ends of the unit pixel 30 arranged in the second direction D2.

In some implementations, the second pixel isolation structure 320 may be disposed in a recessed structure that is recessed in the third direction D3 from the second surface 820. The second pixel isolation structure 320 may be disposed to contact the first pixel isolation structure 310 at one side of the unit pixel 30 (e.g., at the left side of FIG. 8).

In some implementations, the third pixel isolation structure 330 may be disposed in a recessed structure that is recessed in the third direction D3 from the second surface 820. The third pixel isolation structure 330 may be disposed to contact the first pixel isolation structure 310 at the other side of the unit pixel 30 (e.g., at the right side of FIG. 8).

The pixel insulation structure 350 may be disposed in a recessed structure that is recessed in the third direction D3 from the second surface 820. The pixel insulation structure 350 may have a smaller recess depth than each of the first to third pixel isolation structures (310, 320, 330). The pixel insulation structure 350 may be disposed adjacent to each of the second pixel isolation structure 320 and the third pixel isolation structure 330. When a voltage is applied to the gate (SFG) of the source follower transistor, the pixel insulation structure 350 may prevent carriers in a carrier movement channel, which can be formed under the gate (SFG) of the source follower transistor, from moving toward the second direction D2 and leaking to the outside.

The gate (SFG) of the source follower transistor may be disposed on the second surface 820 of the semiconductor substrate 850. The gate (SFG) of the source follower transistor may be disposed in a region between pixel insulation structures 350 located at both sides of the gate (SFG) of the source follower transistor. Each of the source and the drain of the source follower transistor may be arranged in the first direction D1 with respect to the gate (SFG) of the source follower transistor.

The gate (SFG) of the source follower transistor may include metal. The gate (SFG) of the source follower transistor may further include an insulation material. For example, the gate (SFG) of the source follower transistor may include a structure in which a gate insulation layer containing an insulation material is disposed on the second surface 820 and a gate metal layer is disposed on the gate insulation layer.

The epitaxial region 830 may be a region that is not doped with impurities. The epitaxial region 830 may refer to a region in which a first pixel isolation structure 310, a second pixel isolation structure 320, a third pixel isolation structure 330, and a pixel insulation structure 350 are not arranged in a semiconductor substrate 850.

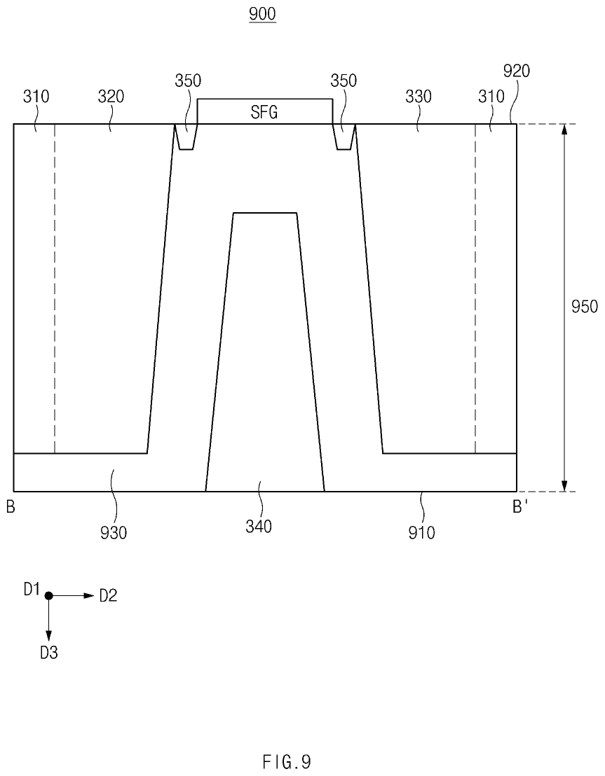

FIG. 9 is a cross-sectional view illustrating an example of the unit pixel taken along the line B-B′ of FIG. 7 based on some implementations of the disclosed technology.

Referring to FIGS. 7 and 9, a second cross-section 900 of the unit pixel 30 taken along the line B-B′ of FIG. 7 may be an example of a cross-section of the unit pixel 30 taken along the line B-B′. Although the second cross-section 900 is a cross-section taken along the line B-B′ of FIG. 7, a cross-section of another portion (i.e., a portion taken along a line crossing the unit pixel 30 in the second direction D2 between the first photoelectric conversion element PD1 and the second photoelectric conversion element PD2) taken along the line B-B′ may also have substantially the same structure as the second cross-section 900.

Hereinafter, in the below, the differences between the structure of FIG. 8 and the structure of FIG. 9 are mainly discussed to avoid redundant description.

The second cross-section 900 may include a semiconductor substrate 950, an epitaxial region 930, a first pixel isolation structure 310, a second pixel isolation structure 320, a third pixel isolation structure 330, a fourth pixel isolation structure 340, a pixel insulation structure 350, and a gate (SFG) of a source follower transistor.

The fourth pixel isolation structure 340 may be disposed in a structure that faces the second surface 920 of the semiconductor substrate 950 and is recessed in the third direction D3 from the first surface 910 upon which light is incident. The fourth pixel isolation structure 340 may be disposed between the second pixel isolation structure 320 and the third pixel isolation structure 330.

The epitaxial region 930 may be a region that is not doped with impurities. The epitaxial region 930 may refer to a region in which a first pixel isolation structure 310, a second pixel isolation structure 320, a third pixel isolation structure 330, a fourth pixel isolation structure 340, and a pixel insulation structure 350 are not arranged in the semiconductor substrate 950.

The description of the constituent components of FIG. 8, which can respectively correspond to the constituent components of FIG. 9, can also be applied to the constituent components of FIG. 9 as long as the description provided in relation to FIG. 8 does not conflict with the description of the constituent components of FIG. 9.

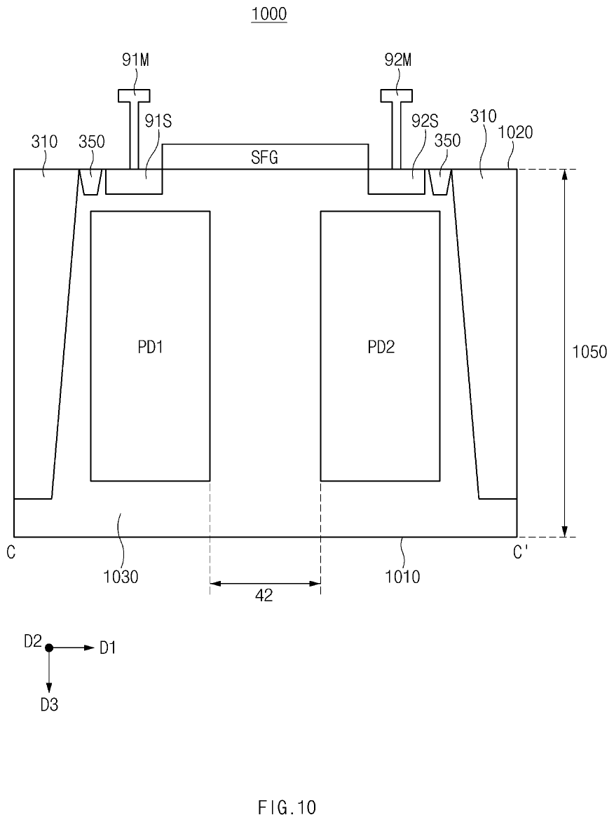

FIG. 10 is a cross-sectional view illustrating an example of the unit pixel taken along the line C-C′ of FIG. 4 based on some implementations of the disclosed technology.

Referring to FIGS. 4 and 10, a third cross-section 1000 of the unit pixel 30 taken along the line C-C′ of FIG. 4 may be an example of a cross-section of the unit pixel 30 taken along the line C-C′. Although the third cross-section 1000 is a cross-section taken along the line C-C′ of FIG. 4, a cross-section of another portion (i.e., a portion taken along a line crossing the gate (SFG) of the source follower transistor in the first direction D1) taken along the line C-C′ may also have substantially the same structure as the third cross-section 1000.

The third cross-section 1000 may include a semiconductor substrate 1050, an epitaxial region 1030, a first pixel isolation structure 310, a first photoelectric conversion element (PD1), a second photoelectric conversion element (PD2), a pixel insulation structure 350, a gate (SFG) of the source follower transistor, and the source and drain (91S, 92S) of the source follower transistor.

The semiconductor substrate 1050 may include a first surface 1010 and a second surface 1020 facing or opposite to the first surface 1010. The semiconductor substrate 1050 may include a silicon material. The first surface 1010 may be a back surface upon which light is incident. The second surface 1020 may be a front surface.

The first pixel isolation structure 310 may be disposed in a recessed structure that is recessed from the second surface 1020 at both ends of the unit pixel 30.

The first photoelectric conversion element (PD1) may be disposed in the semiconductor substrate 1050 while being spaced apart from the first surface 1010 upon which light is incident. The first photoelectric conversion element (PD1) may be a region doped with impurities.

The second photoelectric conversion element (PD2) may be disposed in the semiconductor substrate 1050 while being spaced apart from the first surface 1010 upon which light is incident. The second photoelectric conversion element (PD2) may be disposed in the semiconductor substrate 1050 while being spaced apart from the first photoelectric conversion element (PD1). A space between the first photoelectric conversion element (PD1) and the second photoelectric conversion element (PD2) may be a second gap region 42 shown in FIG. 4. The second photoelectric conversion element (PD2) may be a region doped with impurities.

The pixel insulation structure 350 may be disposed in a recessed structure that is recessed in the third direction D3 from the second surface 1020. The pixel insulation structure 350 may have a smaller recess depth than the first pixel isolation structure 310. The pixel insulation structure 350 may be disposed adjacent to the first pixel isolation structure 310.

The gate (SFG) of the source follower transistor may be disposed on the second surface 1020 of the semiconductor substrate 1050. The gate (SFG) of the source follower transistor may be arranged to extend in the first direction D1. When the gate (SFG) of the source follower transistor increases in size by extending in the first direction D1, noise of the image sensing device may be reduced. The gate (SFG) of the source follower transistor may overlap the first photoelectric conversion element (PD1) when viewed in the third direction D3. The gate (SFG) of the source follower transistor may overlap the second photoelectric conversion element (PD2) when viewed in the third direction D3.

The gate (SFG) of the source follower transistor may include a gate insulation layer disposed on the second surface 1020 and configured to include an insulation material, and a gate electrode layer disposed on the gate insulation layer and configured to include a metal material.

The source and drain (91S, 92S) of the source follower transistor may be respectively disposed at both ends of the gate (SFG) of the source follower transistor arranged in the first direction D1.

The source 91S of the source follower transistor may be electrically connected to one terminal (e.g., a drain region of the selection transistor) of the gate (SELG) of the selection transistor shown in FIG. 4. The source 91S of the source follower transistor and the drain region (not shown) of the selection transistor may be electrically connected to each other through a first metal interconnect layer 91M that may be disposed on the semiconductor substrate 1050 and the second surface 1020.

The drain 92S of the source follower transistor may be connected to the power-supply voltage (e.g., VDD of FIG. 3). The power-supply voltage (e.g., VDD of FIG. 3) may be applied to the drain 92S of the source follower transistor through the second metal interconnect layer 92M.

The epitaxial region 1030 may be or include a region that is not doped with impurities. The epitaxial region 1030 may refer to a region in which the first photoelectric conversion element PD1, the second photoelectric conversion element PD2, the source 91S of the source follower transistor, the drain 92S of the source follower transistor, the first pixel isolation structure 310, and the pixel insulation structure 350 are not arranged in the semiconductor substrate 1050.

The description of the constituent components of FIG. 7, which can respectively correspond to the constituent components of FIG. 10, can also be applied to the constituent components of FIG. 10 as long as the description provided in relation to FIG. 7 does not conflict with the description of the constituent components of FIG. 10.

FIG. 11 is a cross-sectional view illustrating an example of the unit pixel taken along the line D-D′ of FIGS. 4 to 7 based on some implementations of the disclosed technology.

Referring to FIGS. 4 and 11, a fourth cross-section 1100 of the unit pixel 30 taken along the line D-D′ of FIG. 4 may be an example of a cross-section of the unit pixel 30 taken along the line D-D′. Although the fourth cross-section 1100 is a cross-section taken along the line D-D′ of FIG. 4, a cross-section of another portion (i.e., a portion taken along a line that simultaneously crosses the gate (TXG1) of the first transfer transistor and the gate (TXG2) of the second transfer transistor) taken along the line D-D′ may also have substantially the same structure as the fourth cross-section 1100.

The fourth cross-section 1100 may include a semiconductor substrate 1150, an epitaxial region 1130, a first pixel isolation structure 310, a third pixel isolation structure 330, a pixel insulation structure 350, a first photoelectric conversion element (PD1), a second photoelectric conversion element (PD2), a gate (TXG1) of the first transfer transistor, a gate (TXG2) of the second transfer transistor, a first floating diffusion region (FD1), a second floating diffusion region.

(FD2), and a third metal interconnect layer 50.

The semiconductor substrate 1150 may include a first surface 1110 upon which light is incident and a second surface 1120 facing or opposite to the first surface 1110.

The first pixel isolation structure 310 may be disposed at both ends of the unit pixel 30, and may include a structure recessed from the second surface 1120 toward the inside of the semiconductor substrate 1150.

The first photoelectric conversion element (PD1) may generate and accumulate photocharges in response to light incident upon the first surface 1110. The first photoelectric conversion element (PD1) may be disposed in the semiconductor substrate 1150 while being spaced apart from the first surface 1110 upon which light is incident.

The second photoelectric conversion element (PD2) may be disposed in the semiconductor substrate 1150 while being spaced apart from the first surface 1110 upon which light is incident. The second photoelectric conversion element (PD2) may be disposed in the semiconductor substrate 1150 while being spaced apart from the first photoelectric conversion element (PD1). A space between the first photoelectric conversion element (PD1) and the second photoelectric conversion element (PD2) may refer to a first gap region 41 shown in FIG. 4. The first gap region 41 may refer to a portion in which the first gap region 41 does not overlap the second gap region 42.

The third pixel isolation structure 330 may be disposed in the semiconductor substrate 1150 within the first gap region 41 of the unit pixel 30.

The pixel insulation structure 350 may be disposed adjacent to the first pixel isolation structure 310 and the third pixel isolation structure 330. In a situation where the voltage is applied to the gate (TXG1) of the first transfer transistor or the gate (TXG2) of the second transfer transistor, when the photocharges generated by the first photoelectric conversion element (PD1) in response to incident light move to the first floating diffusion region (FD1) and the photocharges generated by the second photoelectric conversion element (PD2) in response to incident light move to the second floating diffusion region (FD2), the pixel insulation structure 350 may prevent leakage of such photocharges.

The gate (TXG1) of the first transfer transistor may include a first gate plane portion (TXG1a) and a first gate buried portion (TXG1b). The first gate plane portion (TXG1a) may refer to a region corresponding to an upper portion of the gate (TXG1) of the first transfer transistor, which is above the second surface 1020. The first gate buried portion (TXG1b) may refer to a region corresponding to a lower portion of the gate (TXG1) of the first transfer transistor, which is below the second surface 1120. Thus, the first gate buried portion (TXG1b) may refer to a region corresponding to a portion recessed into the semiconductor substrate 1150. The gate (TXG1) of the first transfer transistor may include a gate insulation layer containing an insulation material, and may include a gate metal layer disposed on the gate insulation layer.

The gate (TXG2) of the second transfer transistor may include a second gate plane portion (TXG2a) and a second gate buried portion (TXG2b). The second gate plane portion (TXG2a) may refer to a region corresponding to the upper portion of the second surface 1120 from among the gate (TXG2) of the second transfer transistor. The second gate buried portion (TXG2b) may refer to a region corresponding to the lower portion of the second surface 1120 from among the gate (TXG2) of the second transfer transistor. That is, the second gate buried portion (TXG2b) may be a region corresponding to a portion recessed into the semiconductor substrate 1150. The gate (TXG2) of the second transfer transistor may include a gate insulation layer containing an insulation material, and may include a gate metal layer disposed on the gate insulation layer.

The first floating diffusion region (FD1) may be disposed adjacent to the second surface 1120, and may be disposed in the semiconductor substrate 1150. The first floating diffusion region (FD1) may overlap the first photoelectric conversion element (PD1) when viewed in the third direction D3. In some implementations, the first floating diffusion region (FD1) may overlap the first gate plane portion (TXG1a) when viewed in the third direction D3. In some other implementations, the first floating diffusion region (FD1) may be spaced apart from the first gate plane portion (TXG1a) when viewed in the third direction D3.

The second floating diffusion region (FD2) may be disposed adjacent to the second surface 1120, and may be disposed in the semiconductor substrate 1150. The second floating diffusion region (FD2) may overlap the second photoelectric conversion element (PD2) when viewed in the third direction D3. In some implementations, the second floating diffusion region (FD2) may overlap the second gate plane portion (TXG2a) when viewed in the third direction D3. In some other implementations, the second floating diffusion region (FD2) may be spaced apart from the second gate plane portion (TXG2a) when viewed in the third direction D3.

The third metal interconnect layer 50 may electrically connect the first floating diffusion region (FD1) and the second floating diffusion region (FD2) to each other. Although the first floating diffusion region (FD1) and the second floating diffusion region (FD2) are shown as separate floating diffusion regions when viewed in the plan views of FIGS. 4 to 7, other implementations are also possible, and it should be noted that the first floating diffusion region (FD1) and the second floating diffusion region (FD2) may be included in one floating diffusion region that is substantially shared by the first photoelectric conversion element (PD1) and the second photoelectric conversion element (PD2) through the third metal interconnect layer 50. The third metal interconnect layer 50 may include a metal material.

The epitaxial region 1130 may be a region that is not doped with impurities. The epitaxial region 1130 may refer to a region in which the first pixel isolation structure 310, the third pixel isolation structure 330, the pixel insulation structure 350, a first floating diffusion region (FD1), the second floating diffusion region (FD2), the buried portion (TXG1b) of the gate (TXG1) of the first transfer transistor, and the gate (TXG2) of the second transfer transistor are not disposed in the semiconductor substrate 1150.

The description of the constituent components of FIG. 8, which can respectively correspond to the constituent components of FIG. 11, can also be applied to the constituent components of FIG. 11 as long as the description provided in relation to FIG. 8 does not conflict with the description of the constituent components of FIG. 11.

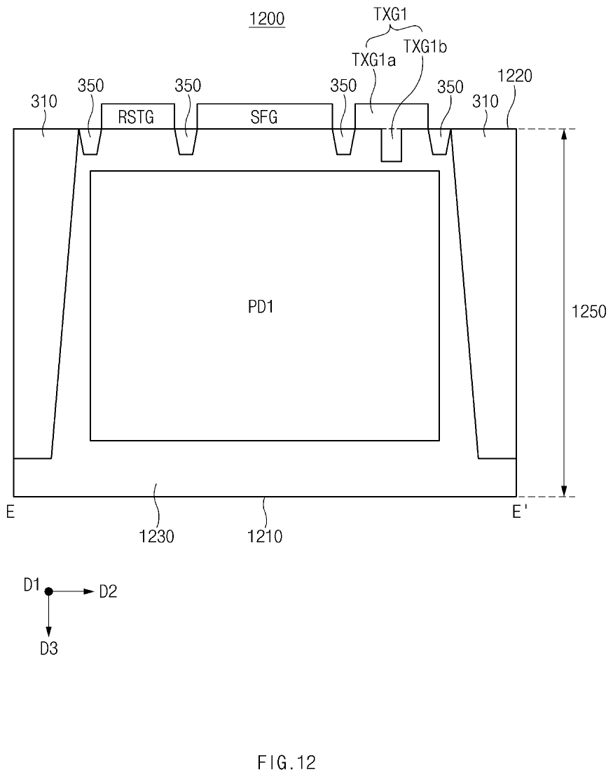

FIG. 12 is a cross-sectional view illustrating an example of the unit pixel taken along the line E-E′ of FIGS. 4 to 7 based on some implementations of the disclosed technology.

Referring to FIGS. 4 and 12, a fifth cross-section 1200 of the unit pixel 30 taken along the line E-E′ of FIG. 4 may be an example of a cross-section of the unit pixel 30 taken along the line E-E′.

Although the fifth cross-section 1200 is a cross-section taken along the line E-E′ of FIG. 4, a cross-section of another portion (i.e., a portion taken along a line crossing the gate (RSTG) of the reset transistor, the gate (SFG) of the source follower transistor, and the gate (TXG1) of the first transfer transistor) taken along the line E-E′ may also have substantially the same structure as the fifth cross-section 1200.

The fifth cross-section 1200 may include a semiconductor substrate 1250, an epitaxial region 1230, a first pixel isolation structure 310, a pixel insulation structure 350, a first photoelectric conversion element (PD1), a gate (SFG) of the source follower transistor, a gate (TXG1) of the first transfer transistor, and a gate (RSTG) of the reset transistor.

The semiconductor substrate 1250 may include a first surface 1210 upon which light is incident, and a second surface 1220 facing or opposite to the first surface 1210.

The first pixel isolation structure 310 may be recessed from the second surface 1220 toward the inside of the semiconductor substrate 1250, and may be disposed at each of both ends of the unit pixel 30.

The pixel insulation structure 350 may be disposed adjacent to the first pixel isolation structure 310. The pixel insulation structure 350 may be further disposed between the gate (RSTG) of the reset transistor and the gate (SFG) of the source follower transistor adjacent to the gate (RSTG) of the reset transistor, and may be further disposed between the gate (SFG) of the source follower transistor and the gate (TXG1) of the first transfer transistor. When a voltage equal to or greater than the threshold voltage is applied to the gate of the transistor, a channel through which carriers can move may be created under the gate of the transistor, and the pixel insulation structure 350 may guide the carriers moving in the channel so as to prevent leakage of such carriers.

The first photoelectric conversion element (PD1) may be disposed between the first pixel isolation structures 310 disposed at both ends of the unit pixel 30 within the semiconductor substrate 1250.

The gate (SFG) of the source follower transistor may be disposed on the second surface 1220. When viewed in the third direction D3, the gate (SFG) of the source follower transistor may overlap the first photoelectric conversion element (PD1).

The gate (TXG1) of the first transfer transistor may be disposed on the second surface 1220. When viewed in the third direction D3, the gate (TXG1) of the first transfer transistor may overlap the first photoelectric conversion element (PD1). The gate (TXG1) of the first transfer transistor may be disposed to be spaced apart from the gate (SFG) of the source follower transistor in the second direction D2.

The gate (RSTG) of the reset transistor may be disposed on the second surface 1220. When viewed in the third direction D3, the gate (RSTG) of the reset transistor may overlap the first photoelectric conversion element (PD1). The gate (RSTG) of the reset transistor may be arranged to be spaced apart from the gate (SFG) of the source follower transistor in the second direction D2. One terminal of the reset transistor may be electrically connected to the first floating diffusion region (FD1) and the second floating diffusion region (FD2), and the other terminal of the reset transistor may be a region to which a power-supply voltage can be applied. The one terminal may correspond to the drain of the reset transistor, the other terminal may correspond to the source of the reset transistor, and each of the source and the drain of the reset transistor may be disposed in the first direction (D1) with respect to the gate (RSTG) of the reset transistor.

The epitaxial region 1230 may be a region that is not doped with impurities. The epitaxial region 1230 may be a region in which the first pixel isolation structure 310, the pixel insulation structure 350, the buried portion (TXG1b) of the gate (TXG1) of the first transfer transistor, and the first photoelectric conversion element (PD1) are not disposed in the semiconductor substrate 1250.

The description of the constituent components of FIG. 8, which can respectively correspond to the constituent components of FIG. 12, can also be applied to the constituent components of FIG. 12 as long as the description provided in relation to FIG. 8 does not conflict with the description of the constituent components of FIG. 12.

As is apparent from the above description, the image sensing device based on some implementations of the disclosed technology can reduce the amount of noise to be generated in electrical signals output from pixels by securing a large gate region of a source follower transistor.

The embodiments of the disclosed technology may provide a variety of effects capable of being directly or indirectly recognized through the above-mentioned patent document.

Although a number of illustrative embodiments have been described, it should be understood that modifications and enhancements to the disclosed embodiments and other embodiments can be devised based on what is described and/or illustrated in this patent document.

What is claimed is:

1. An image sensing device comprising:
a semiconductor substrate configured to include a first surface upon which light is incident from a scene and a second surface facing or opposite to the first surface;
first and second photoelectric conversion elements that are supported by the semiconductor substrate and are spaced apart from each other, each photoelectric conversion element configured to receive incident light and generate photocharges by sensing the received incident light;
a first pixel isolation structure recessed from the second surface and configured to surround the first and second photoelectric conversion elements;
second and third pixel isolation structures disposed between the first photoelectric conversion element and the second photoelectric conversion element and spaced apart from each other; and
a source follower transistor supported by the semiconductor substrate and configured to include a gate disposed on the second surface in at least a portion of a gap region between the second pixel isolation structure and the third pixel isolation structure.

2. The image sensing device according to claim 1, wherein:
the gate of the source follower transistor is disposed to overlap at least one of the first and second photoelectric conversion elements.

3. The image sensing device according to claim 1, wherein:
each of the second pixel isolation structure and the third pixel isolation structure is in contact with the first pixel isolation structure.

4. The image sensing device according to claim 1, further comprising:
a fourth pixel isolation structure disposed in the gap region.

5. The image sensing device according to claim 1, further comprising:
a first floating diffusion region configured to store photocharges that are generated by the first photoelectric conversion element in response to the incident light; and
a second floating diffusion region configured to store photocharges that are generated by the second photoelectric conversion element in response to the incident light.

6. The image sensing device according to claim 5, further comprising:
a first transfer transistor having a first terminal electrically connected to the first photoelectric conversion element and a second terminal electrically connected to the first floating diffusion region; and
a second transfer transistor having a first terminal electrically connected to the second photoelectric conversion element and a second terminal electrically connected to the second floating diffusion region.

7. The image sensing device according to claim 6, wherein:
the gate of the first transfer transistor overlaps the first photoelectric conversion element, and is disposed on the second surface of the semiconductor substrate to be spaced apart from the gate of the source follower transistor; and
the gate of the second transfer transistor overlaps the second photoelectric conversion element, and is disposed on the second surface of the semiconductor substrate to be spaced apart from the gate of the source follower transistor.

8. The image sensing device according to claim 6, wherein:
the gate of the first transfer transistor includes a structure that is recessed from the second surface toward an inside of the semiconductor substrate, and is disposed within the semiconductor substrate to be spaced apart from the first floating diffusion region; and
the gate of the second transfer transistor includes a structure that is recessed from the second surface toward the inside of the semiconductor substrate, and is disposed within the semiconductor substrate to be spaced apart from the second floating diffusion region.

9. The image sensing device according to claim 5, further comprising:
a reset transistor supported by the semiconductor substrate and structured to include a gate that overlaps the first photoelectric conversion element, and is disposed on the second surface of the semiconductor substrate to be spaced apart from the gate of the source follower transistor,
wherein the reset transistor is configured to drain photocharges stored in the first and the second floating diffusion regions.

10. The image sensing device according to claim 1, further comprising:
a selection transistor supported by the semiconductor substrate and structured to include a gate that overlaps the second photoelectric conversion element, and is disposed on the second surface of the semiconductor substrate to be spaced apart from the gate of the source follower transistor,
wherein the selection transistor outputs an electrical signal having a voltage level corresponding to the photocharges generated by the first or second photoelectric conversion element.

11. The image sensing device according to claim 1, further comprising:
a drain transistor supported by the semiconductor substrate and structured to include a gate that overlaps the first photoelectric conversion element, and is disposed on the second surface of the semiconductor substrate to be spaced apart from a gate of the source follower transistor,
wherein the photocharges generated by the first or second photoelectric conversion element are reset by the drain transistor.

12. The image sensing device according to claim 6, further comprising:
a dual conversion gain (DCG) transistor supported by the semiconductor substrate and structured to include a gate that overlaps the first photoelectric conversion element, and is disposed on the second surface of the semiconductor substrate to be spaced apart from the gate of the source follower transistor,
wherein the DCG transistor changes a capacitance of at least one of the first and the second floating diffusion regions.

13. The image sensing device according to claim 5, further including:
a metal interconnect layer configured to contact each of the first floating diffusion region and the second floating diffusion region while being located outside the semiconductor substrate,
wherein
the metal interconnect layer electrically connects the first floating diffusion region and the second floating diffusion region to each other.

14. An image sensing device comprising:
a semiconductor substrate configured to include a first surface upon which light is incident and a second surface facing or opposite to the first surface;
a first photoelectric conversion element supported by the semiconductor substrate and configured to generate photocharges in response to the incident light;
a second photoelectric conversion element supported by the semiconductor substrate and spaced apart from the first photoelectric conversion element, and configured to generate photocharges in response to the incident light; and
a source follower transistor supported by the semiconductor substrate and structured to include a gate disposed in a gap region between the first photoelectric conversion element and the second photoelectric conversion element,
wherein
the gate of the source follower transistor overlaps at least a portion of each of the first photoelectric conversion element and the second photoelectric conversion element that are arranged in a first direction perpendicular to the second surface.

15. The image sensing device according to claim 14, further comprising:
a first transfer transistor supported by the semiconductor substrate and structured to include a gat that overlaps the first photoelectric conversion element in the first direction and is disposed on the second surface of the semiconductor substrate to be spaced apart from the gate of the source follower transistor; and
a second transfer transistor supported by the semiconductor substrate and structured to include a gate that overlaps the second photoelectric conversion element in the first direction and is disposed on the second surface of the semiconductor substrate to be spaced apart from both the gate of the source follower transistor and the gate of the first transfer transistor.

16. The image sensing device according to claim 15, further comprising:
a floating diffusion region supported by the semiconductor substrate within a space between the gate of the first transfer transistor and the gate of the second transfer transistor, and arranged adjacent to the second surface of the semiconductor substrate.

17. The image sensing device according to claim 15, further comprising:
a first floating diffusion region spaced apart from the gate of the first transfer transistor, disposed within the semiconductor substrate, and adjacent to the second surface; and
a second floating diffusion region spaced apart from the gate of the second transfer transistor, disposed within the semiconductor substrate, and adjacent to the second surface.

18. The image sensing device according to claim 17, further comprising:
a metal interconnect layer configured to contact each of the first floating diffusion region and the second floating diffusion region while being located outside the semiconductor substrate,
wherein
the metal interconnect layer electrically connects the first floating diffusion region and the second floating diffusion region to each other.

19. The image sensing device according to claim 14, further comprising:
a pixel isolation structure recessed from the first surface of the semiconductor substrate corresponding to the gap region toward an inside of the semiconductor substrate.

20. The image sensing device according to claim 16, wherein the first photoelectric conversion element and the second photoelectric conversion element are configured to share the floating diffusion region.
